(19) United States
(12) Patent Application Publication
(10) Pub. No.: US 2006/0057785 A1
(43) Pub. Date: Mar. 16, 2006

(54) Method of manufacturing semiconductor device

(76) Inventors: Tomoya Satonaka, Yokohama-shi (JP); Toshiyuki Sasaki, Yamato-shi (JP); Masaki Narita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/994,239

(22) Filed: Nov. 23, 2004

(30) Foreign Application Priority Data
Sep. 15, 2004 (JP) 2004-268722

(51) Int. Cl. H01L 21/00; H01L 21/84

(52) U.S. Cl. 438/149

(57) ABSTRACT

Disclosed is a method of manufacturing a semiconductor device, comprising introducing a work piece comprising a semiconductor substrate, a gate insulation film formed on the semiconductor substrate, and a gate electrode film formed on the gate insulation film, into a chamber, and forming a gate electrode by selectively etching the gate electrode film relative to the gate insulation film by anisotropic dry etching in the chamber, wherein forming the gate electrode includes etching the gate electrode film under a condition that a residence time of an etching gas in the chamber is 100 milliseconds or shorter, at least after a part of the gate insulation film is exposed.

### CROSS-REFERENCE TO RELATED APPLICATIONS

This application is based upon and claims the benefit of priority from prior Japanese Patent Application No. 2004-268722, filed Sep. 15, 2004, the entire contents of which are incorporated herein by reference.

### BACKGROUND OF THE INVENTION

1. Field of the Invention

This invention relates to a method of manufacturing a semiconductor device.

2. Description of the Related Art

As a semiconductor device is finer, formation of a gate electrode having a desired processing shape by anisotropic dry etching becomes gradually difficult (for example, Jpn. Pat. Appln. KOKAI Publication No. 10-172959 and Jpn. Pat. Appln. KOKAI Publication No. 11-54481). When a gate electrode is formed by anisotropic dry etching, it is important to selectively etch a gate electrode film relative to a gate insulation film and make side surfaces of the gate electrode perpendicular to a main surface of a semiconductor substrate. However, if a selective ratio of etching of the gate electrode film to the gate insulation film is increased, the gate electrode becomes tapered. If a gate electrode having the side surfaces of a perpendicular shape is to be formed, the selective ratio of etching is lowered. Thus, in prior art, when the gate electrode is formed by anisotropic dry etching, formation of the gate electrode having a high selective ratio of etching and having side surfaces of a perpendicular shape or a gate electrode having a desired and appropriate processing shape is difficult.

In addition, as a semiconductor device is finer, formation of an isolation trench by anisotropic dry etching becomes gradually difficult. Especially, the following problem arises in a semiconductor device comprising a logic circuit area and a memory area having a trench capacitor. In the memory area, an isolation trench is formed in an area in which a semiconductor portion and an insulation portion exist together (in which a trench capacitor is to be formed). Thus, etching needs to be performed under a condition that the etching rate of the semiconductor portion and the etching rate of the insulation portion are substantially equal to each other. In the logic circuit area, isolation trenches equal in depth but different in width need to be formed in a semiconductor area. In addition, the isolation trenches formed in the memory area and the isolation trenches formed in the logic circuit area need to be equal in depth. However, it is difficult to meet all of these requirements. In prior art, it is difficult to form the isolation trenches having a desired and appropriate processing shape in the mixture area where the semiconductor portion and the insulation portion exist together and the semiconductor area formed of the semiconductor.

As described above, as a semiconductor device is finer, acquiring a desired and appropriate processing shape by anisotropic dry etching becomes gradually difficult and it is therefore difficult to manufacture a semiconductor device excellent in characteristics and reliability.

### BRIEF SUMMARY OF THE INVENTION

According to a first aspect of the present invention, there is provided a method of manufacturing a semiconductor device, comprising: introducing a work piece comprising a semiconductor substrate, a gate insulation film formed on the semiconductor substrate, and a gate electrode film formed on the gate insulation film, into a chamber; and forming a gate electrode by selectively etching the gate electrode film relative to the gate insulation film by anisotropic dry etching in the chamber, wherein forming the gate electrode includes etching the gate electrode film under a condition that a residence time of an etching gas in the chamber is 100 milliseconds or shorter, at least after a part of the gate insulation film is exposed.

According to a second aspect of the present invention, there is provided a method of manufacturing a semiconductor device, comprising: introducing a work piece including a semiconductor area formed of semiconductor and a mixture area where a semiconductor portion and an insulation portion exist together, into a chamber; and forming trenches in each of the semiconductor area and the mixture area by anisotropic dry etching in the chamber, wherein forming the trenches is executed using an etching gas by which an etching rate of the semiconductor portion is substantially equal to an etching rate of the insulation portion and under a condition that a residence time of the etching gas in the chamber is 100 milliseconds or shorter.

### BRIEF DESCRIPTION OF THE SEVERAL VIEWS OF THE DRAWING

FIG. 1 and FIG. 2 are cross-sectional views showing a method of manufacturing a semiconductor device, according to a first embodiment of the present invention;

FIG. 3 is a diagram showing a schematic structure of a processing apparatus applied for the manufacturing method, according to the first and second embodiments of the present invention;

FIG. 4 is an illustration showing a flow of anisotropic dry etching processings, according to the first embodiment;

FIG. 5 is a photograph of an electron microscope showing a cross-sectional shape of a gate electrode, according to the first embodiment;

FIG. 6 is a photograph of an electron microscope showing a cross-sectional shape of a gate electrode, according to a comparative example of the first embodiment;

FIG. 7A to FIG. 7C, and FIG. 8A to FIG. 8C are cross-sectional views showing a method of manufacturing a semiconductor device according to the second embodiment of the present invention; and

FIG. 9 is a graph showing a relationship between a trench width and a trench depth, according to the second embodiment.

### DETAILED DESCRIPTION OF THE INVENTION

Embodiments of the present invention will be explained below with reference to the accompanying drawings.

### First Embodiment

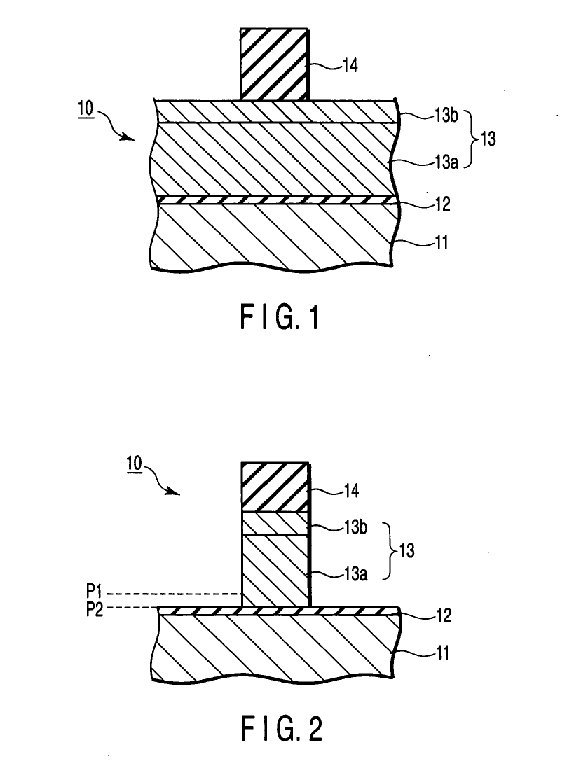

FIG. 1 and FIG. 2 show cross-sectional views of a method of manufacturing a semiconductor device, according to a first embodiment of the present invention. In the present embodiment, a gate electrode is formed by anisotropic plasma dry etching.

First, a work piece 10 shown in FIG. 1 is prepared. The work piece 10 comprises a semiconductor substrate (semiconductor wafer) 11, a gate insulation film 12 formed on the semiconductor substrate 11, a gate electrode film 13 formed on the gate insulation film 12, and a hard mask 14 formed on the gate electrode film 13. The semiconductor substrate 11 is formed of a silicon substrate. The gate insulation film 12 is formed of a silicon oxide film. The gate electrode film 13 is formed of a polysilicon film 13a and a W silicide film 13b. The hard mask 14 is formed of a silicon nitride film.

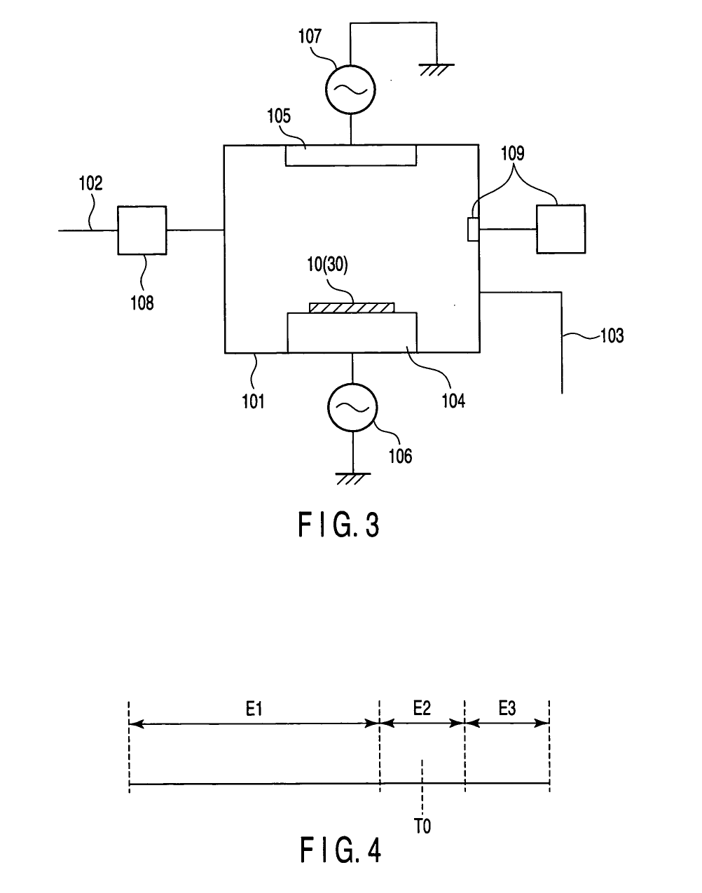

Next, the work piece 10 is etched by a processing apparatus for anisotropic plasma dry etching. FIG. 3 shows a schematic diagram of the processing apparatus. A basic structure of the processing apparatus is similar to that of a general RIE (reactive ion etching) apparatus, comprising a chamber 101, a gas inlet line 102, a discharge line 103, a lower electrode (susceptor) 104, an upper electrode 105, a lower electrode power supply 106, an upper electrode power supply 107, a flowmeter 108, and a pressure gauge 109. The chamber 101 is remarkably smaller than a general anisotropic dry etching apparatus and has a volume (capacity) of 10 litters or less (5.5 litters in the present embodiment).

The work piece 10 is placed on the lower electrode 104 in the chamber 101, and the gate electrode film 13 is subjected to selective etching relative to the gate insulation film 12, with the hard mask 14 serving as a mask, by anisotropic dry etching, as shown in FIG. 2. FIG. 4 shows a processing flow of the anisotropic dry etching.

As shown in FIG. 4, the gate electrode film 13 is etched by etching processings E1, E2 and E3. In the etching processings E2 and E3, etching is executed under a condition that a residence time of an etching gas in the chamber 101 is 100 milliseconds or shorter. In the etching processing E1, etching may be executed under a condition that the residence time of the etching gas in the chamber 101 is 100 milliseconds or shorter or a condition that the residence time is longer than 100 milliseconds.

The residence time is directly proportional to the volume (capacity) of the chamber and the pressure therein, and inversely proportional to a flow rate of the etching gas. If the volume of the chamber is represented by V (litter), the pressure in the chamber is represented by P (Torr) and the flow rate of the etching gas is represented by F (sccm), the residence time T (second) can be represented by:
T=(V×P)/(1.27×10⁻²×F) (1)

The volume V is preliminarily known (5.5 litters in the present embodiment). The pressure P can be acquired by the pressure gauge 109 and the flow rate F can be acquired by the flowmeter 108. The residence time T can be therefore acquired from formula (1).

Details of the etching processings will be explained below.

In the etching processing E1, the W silicide film 13b and the polysilicon film 13a are subjected to anisotropic etching. The polysilicon film 13a is not completely etched but etched to, for example, a position P1 of FIG. 2. In other words, polysilicon film 13a is left on the gate insulation film 12 and the gate insulation film 12 is not exposed. Thus, in the etching processing E1, a ratio of the etching rate of the polysilicon film 13a to the etching rate of the gate insulation film 12 (i.e. selective ratio) may not be so high and it is preferable to execute the etching under a condition of highly anisotropic etching by increasing the ion energy.

After the etching processing E1 has been ended, the etching processing E2 is executed. The end point of the etching processing E1 may be determined with reference to a preset etching time or the thickness of the polysilicon film 13a. The thickness of the polysilicon film 13a can be detected by, for example, monitoring the interference waveform.

In the etching processing E2, HBr is used as the etching gas, and the polysilicon film 13a is subjected to anisotropic etching until a substantially entire surface of the gate insulation film 12 is exposed. In other words, the polysilicon film 13a is etched to a position P2 of FIG. 2. Since the surface of the gate insulation film 12 is not simultaneously exposed with the entire surface of the wafer, exposure of a part of the gate insulation film 12 starts at time T0 during the etching processing E2 and the exposed area of the gate insulation film 12 is gradually extended. Since the exposure of the gate insulation film 12 starts at time T0 in the etching processing E2, the selective ratio of etching of the polysilicon film 13a to the gate insulation film 12 needs to be sufficiently high. Thus, in the etching processing E2, etching is executed under a condition that the residence time of the etching gas in the chamber 101 is 100 milliseconds or shorter. Under such a condition, etching can be executed at the high selective ratio, with high anisotropy, as described later.

After the etching processing E2 has been ended, the etching processing E3 is executed. The end point of the etching processing E2 can be determined by, for example, detecting the time when a substantially entire surface of the gate insulation film 12 is exposed from the variation in the light-emitting intensity of the plasma in the chamber.

In the etching processing E3, overetching is executed to completely remove the polysilicon film 13a formed in the area other than the area located under the hard mask 14. A mixture gas of HBr and O₂ is used as the etching gas. In the over-etching, too, the selective ratio of etching of the polysilicon film 13a to the gate insulation film 12 needs to be sufficiently high. For this reason, in the etching processing E3, too, etching is executed under a condition that the residence time of the etching gas in the chamber 101 is 100 milliseconds or shorter. In addition, since the gate insulation film 12 is exposed in the beginning of the etching processing E3, it is preferable to make the selective ratio of etching higher than that of the etching processing E2. The selective ratio of etching can be made higher by adding O₂ to HBr.

Thus the structure shown in FIG. 2 can be obtained by executing the etching processing E1, etching processing E2 and etching processing E3.

As described above, in the etching processing E2 and etching processing E3 of the present embodiment, etching is executed under a condition that the residence time of the etching gas in the chamber 101 is 100 milliseconds or shorter. If the residence time of the etching gas is long, the residence time of a reactive product caused by the etching is also long inevitably. For this reason, the reactive product can easily be deposited on the side surfaces of the polysilicon film 13a and preferable anisotropic etching is prohibited by the deposited reactive product. As a result, the gate electrode becomes tapered. In the present embodiment, since the residence time is short, deposition of the reactive product on the side surfaces of the polysilicon film 13a can be restricted and the gate electrode having the side surfaces of a perpendicular shape can be obtained. Further, if the residence time of the etching gas is long, the rate of dissociation of the etching gas in the chamber 101 becomes high. For this reason, the gate insulation film 12 is easily etched by dissociated active ions and radicals and the selective ratio of etching is lowered. In the present embodiment, since the residence time is short, the rate of dissociation of the etching gas becomes lowered and the selective ratio of etching can be high. Thus, according to the present embodiment, the gate electrode of the high selective ratio of etching, having side surfaces of a perpendicular shape can be formed and the semiconductor device excellent in characteristics and reliability can be formed.

When an N-type MOS transistor and a P-type MOS transistor are formed on a common wafer, it is difficult to obtain the gate electrode (N-type polysilicon) of the N-type MOS transistor, having a perpendicular shape compared to the gate electrode (P-type polysilicon) of the P-type MOS transistor, under general etching conditions. However, if etching is executed under a condition that the residence time is 100 milliseconds or shorter, the gate electrode of a perpendicular shape can be obtained in each of the N-type MOS transistor and the P-type MOS transistor.

In addition, in the present embodiment, the volume of the chamber is remarkably smaller than a general chamber, i.e. 10 litters or smaller, to make the residence time shorter. As understood from formula (1), the residence time can also be made shorter by lowering the pressure P in the chamber. If the pressure in the chamber is lowered, however, the sputtering effect of ions may be enhanced and the gate insulation film may be etched by the sputtering. In the present embodiment, since the residence time is shortened by making the volume of the chamber small, etching of the gate insulation film caused by the sputtering effect can be restricted.

FIG. 5 is a photograph of an electron microscope showing a cross-sectional shape of the gate electrode formed in the method of the present embodiment. The etching processing E1 was executed under the condition that the selective ratio of etching is comparatively low. The etching processing E2 and etching processing E3 were executed under the condition that the residence time is 100 milliseconds or shorter.

The specific conditions of etching in the etching processing E2 were as follows:
Volume of Chamber: 5.5 litters,
Pressure in Chamber: 5 mTorr,
Etching Gas: HBr
Flow Rate of Etching Gas: HBr=100 sccm,
Power supplied to Upper Electrode/Lower Electrode: 200 W/50 W

The residence time was 21.7 milliseconds from formula (1). The etching rate of the polysilicon film was 128.5 nm/min. and the selective ratio of etching of the polysilicon film to the gate insulation film (silicon oxide film) was 229.1.

The specific conditions of etching in the etching processing E3 were as follows:
Volume of Chamber: 5.5 litters,
Pressure in Chamber: 30 mTorr,
Etching Gases: HBr and O₂,
Flow Rates of Etching Gases:
   HBr=185 sccm,
   O₂=5 sccm,
Power supplied to Upper Electrode/Lower Electrode: 200 W/0 W

The residence time was 68.4 milliseconds from formula (1). The etching rate of the polysilicon film was 72.3 nm/min. and the selective ratio of etching of the polysilicon film to the gate insulation film (silicon oxide film) was infinite.

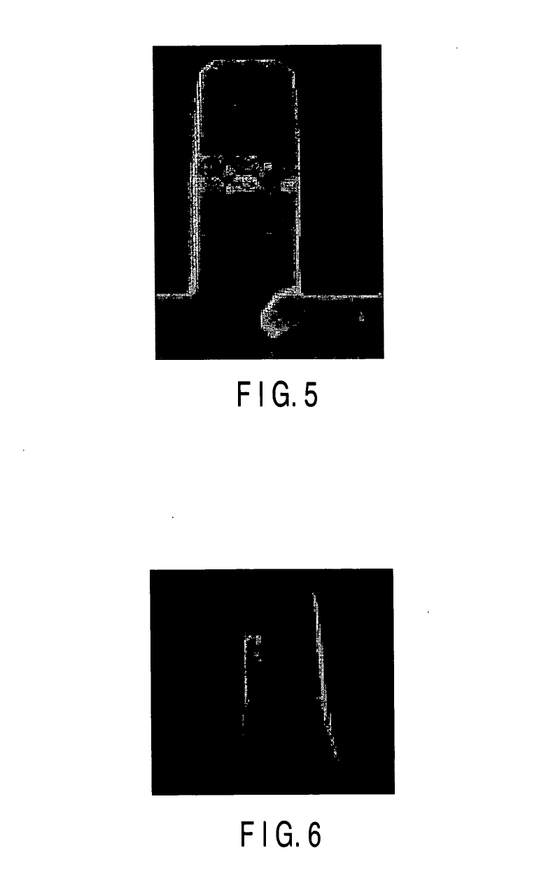

FIG. 6 is a photograph of an electron microscope showing the cross-sectional shape of the gate electrode according to a comparative example. The etching processing E1 was executed under the condition that the selective ratio of etching is comparatively low, similarly to the processing of FIG. 5. The etching processing E2 and etching processing E3 were executed under a condition that the residence time is longer than 100 milliseconds.

The specific conditions of etching in the etching processing E2 were as follows:
Volume of Chamber: 36 litters,
Pressure in Chamber: 5 mTorr,
Etching Gas: HBr
Flow Rate of Etching Gas: HBr=100 sccm,
Power supplied to Upper Electrode/Lower Electrode: 200 W/50 W

The residence time was 141.7 milliseconds from formula (1).

The specific conditions of etching in the etching processing E3 were as follows:
Volume of Chamber: 36 litters,
Pressure in Chamber: 30 mTorr,
Etching Gases: HBr and O₂,
Flow Rates of Etching Gases:
   HBr=185 sccm,
   O₂=5 sccm,
Power supplied to Upper Electrode/Lower Electrode: 200 W/0 W

The residence time was 447.6 milliseconds from formula (1).

As clarified from comparison of FIG. 5 and FIG. 6, perpendicularity of the side surfaces of the gate electrode can be remarkably improved by executing the etching processing E2 and etching processing E3 under the condition that the residence time is 100 milliseconds or shorter.

In the present embodiment, if the gate electrode film is etched under the condition that the residence time is 100 milliseconds or shorter at least after a part of the gate insulation film is exposed, the above-described advantage can be obtained. In fact, however, since it is not easy to determine the time when a part of the gate insulation film is exposed, it is preferable that the gate electrode film should be etched under the condition that the residence time is 100 milliseconds or shorter before a part of the gate insulation film is exposed as described above.

The etching processing E3 (over-etching processing) may be executed under the same conditions as those of the etching processing E2. As explained above, however, since a substantially entire surface of the gate insulation film 12 has been exposed at the start of the etching processing E3, it is preferable that the etching conditions should be changed from those of the etching processing E2 so as to obtain a higher selective ratio of etching.

Moreover, HBr was used as the etching gas in the etching processing E2, and a mixture gas of HBr and O₂ was used in the etching processing E3, as the etching processing under the condition that the residence time is 100 milliseconds or shorter. However, a gas such as N₂, Cl₂, or the like may be added to these gases. Generally speaking, at least Br needs to be contained in the etching gas in the etching processing executed under the condition that the residence time is 100 milliseconds or shorter.

### Second Embodiment

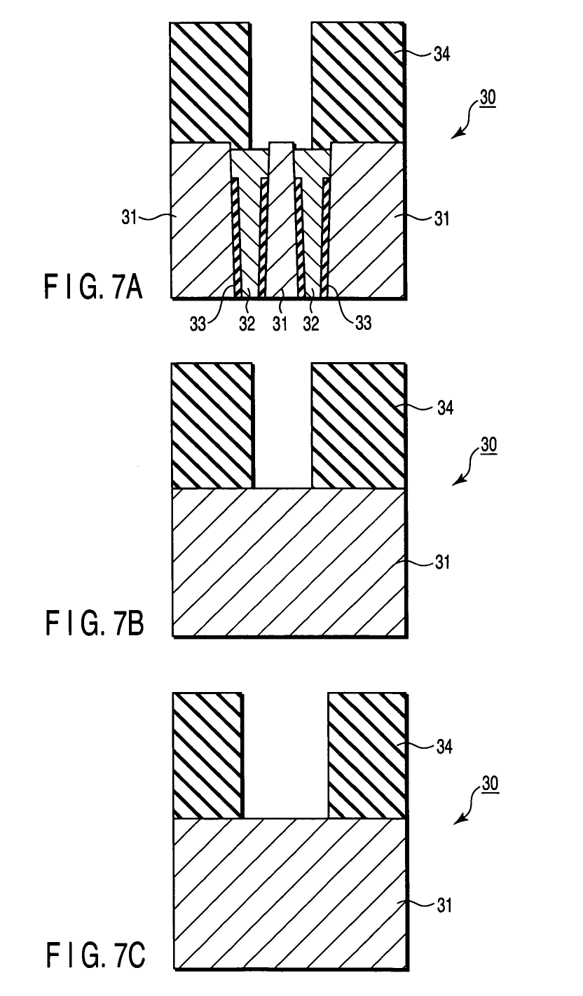

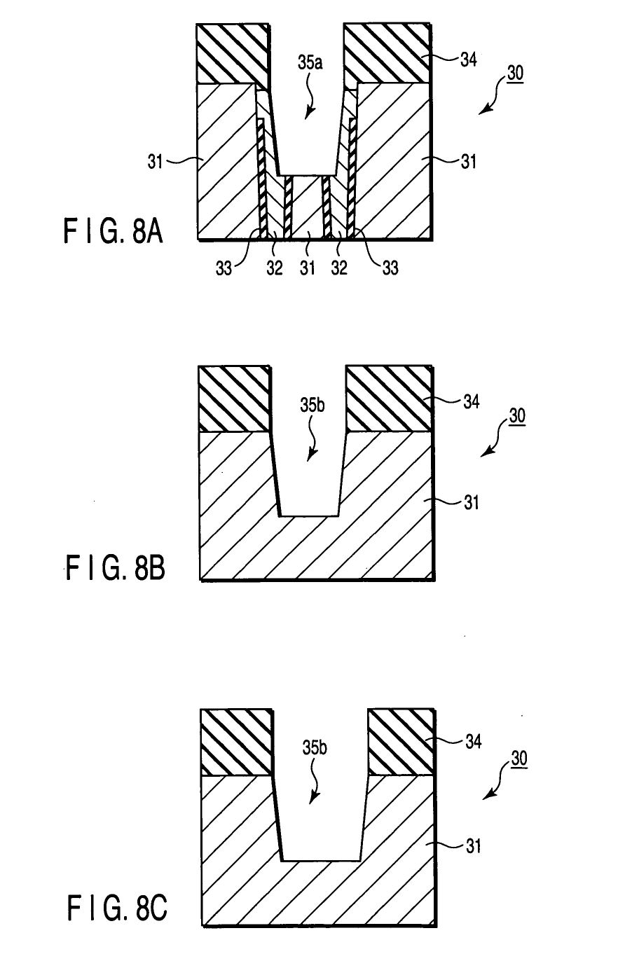

FIG. 7A to FIG. 7C, and FIG. 8A to FIG. 8C show cross-sectional views of a method of manufacturing a semiconductor device according to the second embodiment of the present invention. In the present embodiment, an isolation trench, i.e. a trench for STI (shallow trench isolation) is formed by anisotropic plasma dry etching.

First, a work piece 30 as shown in FIG. 7A, FIG. 7B and FIG. 7C is prepared. The work piece 30 is used to manufacture a semiconductor device including a memory area and a logic circuit area.

In the memory area, a trench for trench capacitor is formed in a semiconductor substrate (semiconductor wafer) 31 and a semiconductor film 32 and a capacitor insulation film (dielectric film) 33 are formed in the trench as shown in FIG. 7A. The semiconductor substrate 31 and the semiconductor film 32 are formed of silicon. The insulation film 33 is formed of silicon oxide. In other words, the memory area includes a mixture area where a semiconductor portion (semiconductor substrate 31 and semiconductor film 32) and an insulation portion (insulation film 33) exist together. A hard mask 34 is formed on the mixture area as an etching mask which is to be used at formation of an isolation trench. In the present embodiment, a silicon oxide film is used as the hard mask 34.

In the logic circuit area, a hard mask 34 is formed on the semiconductor substrate 31, i.e. the semiconductor area as an etching mask which is to be used at formation of an isolation trench, as shown in FIG. 7B and FIG. 7C. As understood from FIG. 7B and FIG. 7C, the width of the isolation trench is not constant, but a plurality of isolation trenches having a plurality of widths are formed, in the logic circuit area.

Next, the work piece 30 is etched by a processing apparatus for anisotropic plasma dry etching. The basic structure of the processing apparatus is the same as that of the processing apparatus of the first embodiment shown in FIG. 3. The volume (capacity) of the chamber 101 is 10 litters or smaller (5.5 litters in the present embodiment). The work piece 30 is placed on the lower electrode 104 in the chamber 101 and etched by anisotropic dry etching using the hard mask 34 as a mask. As an etching gas, for example, a mixture gas of HBr and SF₆ is used. As a result, in the memory area, the semiconductor substrate 31, the semiconductor films 32 and the capacitor insulation films 33 are etched and a plurality of isolation trenches 35a having an equal width are thereby formed, as shown in FIG. 8A. In the logic circuit area, the semiconductor substrate 31 is etched and a plurality of isolation trenches 35b different in width are thereby formed, as shown in FIG. 8B and FIG. 8C.

In the memory area, since the semiconductor portion (semiconductor substrate 31 and semiconductor film 32) formed of silicon and the insulation portion (insulation film 33) formed of a silicon oxide film exist together, anisotropic dry etching needs to be executed under a condition that the etching rate of the semiconductor portion is substantially equal to the etching rate of the insulation portion. In the logic circuit area, the isolation trenches which are substantially equal in depth and different in width need to be formed. Moreover, the depth of the isolation trenches in the memory area needs to be substantially equal to the depth of the isolation trenches in the logic circuit area. The etching rate of the semiconductor portion can be tentatively made substantially equal to the etching rate of the insulation portion, by using the mixture gas of HBr and SF₆ as the etching gas. By merely using such an etching has, however, the depth of the isolation trenches of small width becomes smaller than the isolation trenches of great width, due to the so-called microloading effect. Thus, according to the general etching method, it is extremely difficult to form the isolation trenches which meet the condition of making the semiconductor portion and the insulation portion substantially equal in etching rate, and which have a substantially equal depth not depending on the trench width, in the memory area and the logic circuit area.

In the present embodiment, etching is executed under a condition that the residence time of the etching gas in the chamber 101 is 100 milliseconds or shorter, in order to prevent the above problems from occurring. By executing the etching under such a condition, the isolation trenches which have a substantially equal depth not depending on the trench width, can be formed under a condition that a ratio (selective ratio of etching) of the etching rate of the semiconductor portion to the etching rate of the isolation portion is substantially 1 (for example, approximately 0.8 to 1.2).

As described above, the isolation trenches having different widths are formed in the logic circuit area. In the isolation trench having a greater width, since the reactive product generated by the etching is easily discharged from the trench, the etching can easily proceed. In the isolation trench having a smaller width, however, since the reactive product is hardly discharged from the trench, the etching hardly proceeds. If the residence time of the etching gas is long, the residence time of the reactive product generated by the etching also becomes long inevitably. Therefore, the reactive product is hardly discharged from the trench. For this reason, if the etching is executed under the condition that the residence time is long, the depth of the isolation trench having a greater width is relatively greater and the depth of the isolation trench having a smaller width is relatively smaller. In the present embodiment, since the residence time is short, the reactive product can easily be discharged from the isolation trench having a smaller width, and the etching easily proceeds in the isolation trench having a smaller width. Therefore, according to the present embodiment, the isolation trenches having a substantially equal depth irrespective of the trench width can be formed under the condition that the semiconductor portion and the isolation portion are substantially equal in etching rate, and the semiconductor device excellent in characteristics and reliability can be formed.

In addition, in the present embodiment, the volume (capacity) of the chamber is 10 litters or smaller, to make the residence time shorter. As understood from formula (1), the residence time can be shortened by lowering the pressure P in the chamber. However, if the pressure in the chamber is too lowered, the selective ratio of etching may be varied or desired etching conditions cannot be obtained. In the present embodiment, since the residence time is shortened by making the volume of the chamber smaller, the etching can be certainly executed under desired etching conditions.

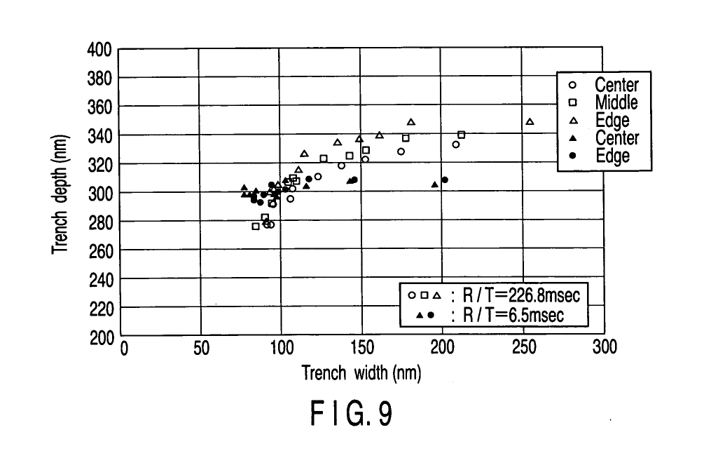

FIG. 9 is a graph of a measurement result to prove the above-described effect. In the graph, the lateral axis represents the width of the isolation trench and the longitudinal axis represents the depth of the trench. The measured portions are a center, an edge and their middle of the wafer.

The conditions of etching a sample under the condition that the residence time is 100 milliseconds or shorter were as follows:
Volume of Chamber: 5.5 litters,
Pressure in Chamber: 3 mTorr,
Etching Gases: HBr and SF₆,
Flow Rates of Etching Gases:
   HBr=120 sccm,
   SF₆=80 sccm,
Power supplied to Upper Electrode/Lower Electrode: 800 W/200 W

The residence time was 6.5 milliseconds from formula (1).

The conditions of etching a sample under the condition that the residence time is longer than 100 milliseconds were as follows:
Volume of Chamber: 36 litters,
Pressure in Chamber: 8 mTorr,
Etching Gases: HBr and SF₆,
Flow Rates of Etching Gases:
   HBr=60 sccm,
   SF₆=40 sccm,
Power supplied to Upper Electrode/Lower Electrode: 1000 W/200 W

The residence time was 226.8 milliseconds from formula (1).

As understood from FIG. 9, if the etching is executed under the condition that the residence time is longer than 100 milliseconds, the trench depth is varied in accordance with the trench width. However, if the etching is executed under the condition that the residence time is 100 milliseconds or shorter, the isolation trenches having a substantially equal depth can be formed irrespective of the trench width.

In the above-described embodiment, the mixture gas of HBr and SF₆ was used as the etching gas, in the etching processing under the condition that the residence time is 100 milliseconds or shorter. However, at least F only needs to be contained in the etching gas. Specific examples of the gas containing F are SF₆, NF₃, CF₄, and the like.

According to the above-described first and second embodiments, the chamber having a volume of 10 litters or less was used to obtain the condition that the residence time of the etching gas in the chamber is 100 milliseconds or shorter. However, if the condition that the residence time of the etching gas is 100 milliseconds or shorter can be obtained, the chamber having a volume of 10 litters or less does not definitely need to be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
introducing a work piece comprising a semiconductor substrate, a gate insulation film formed on the semiconductor substrate, and a gate electrode film formed on the gate insulation film, into a chamber; and
forming a gate electrode by selectively etching the gate electrode film relative to the gate insulation film by anisotropic dry etching in the chamber,
wherein forming the gate electrode includes etching the gate electrode film under a condition that a residence time of an etching gas in the chamber is 100 milliseconds or shorter, at least after a part of the gate insulation film is exposed.

2. The method according to claim 1, wherein etching the gate electrode film at least after a part of the gate insulation film is exposed, includes etching the gate electrode film under a condition that a residence time of an etching gas in the chamber is 100 milliseconds or shorter, before a part of the gate insulation film is exposed.

3. The method according to claim 1, wherein etching the gate electrode film at least after a part of the gate insulation film is exposed, includes executing over-etching after a substantially entire surface of the gate insulation film is exposed except a portion under the gate electrode.

4. The method according to claim 1, wherein the gate insulation film is formed of a silicon oxide film.

5. The method according to claim 1, wherein the gate electrode includes a polysilicon film.

6. The method according to claim 1, wherein the etching gas contains at least Br.

7. The method according to claim 1, wherein the chamber has a volume of 10 litters or less.

8. The method according to claim 1, wherein residence time T (second) of the etching gas is represented by:
T=(V×P)/(1.27×10⁻²×F)
where V (litter) represents a volume of the chamber, P (Torr) represents a pressure in the chamber, and F (sccm) represents a flow rate of the etching gas.

9. A method of manufacturing a semiconductor device, comprising:
introducing a work piece including a semiconductor area formed of semiconductor and a mixture area where a semiconductor portion and an insulation portion exist together, into a chamber; and
forming trenches in each of the semiconductor area and the mixture area by anisotropic dry etching in the chamber,
wherein forming the trenches is executed using an etching gas by which an etching rate of the semiconductor portion is substantially equal to an etching rate of the insulation portion and under a condition that a residence time of the etching gas in the chamber is 100 milliseconds or shorter.

10. The method according to claim 9, wherein a plurality of trenches substantially equal in depth and different in width are formed in the semiconductor area by the anisotropic dry etching.

11. The method according to claim 9, wherein the trench formed in the semiconductor area and the trench formed in the mixture area have a substantially equal depth.

12. The method according to claim 9, wherein the semiconductor area and the semiconductor portion are formed of silicon.

13. The method according to claim 9, wherein the insulation portion is formed of silicon oxide.

14. The method according to claim 9, wherein the etching gas contains at least F.

15. The method according to claim 9, wherein a capacitor is to be formed in the mixture area.

16. The method according to claim 9, wherein the chamber has a volume of 10 liters or less.

17. The method according to claim 9, wherein residence time T (second) of the etching gas is represented by:
T=(V×P)/(1.27×10⁻²×F)
where V (litter) represents a volume of the chamber, P (Torr) represents a pressure in the chamber, and F (sccm) represents a flow rate of the etching gas.

18. The method according to claim 9, wherein the semiconductor area is included in a logic circuit area and the mixture area is included in a memory area.

19. The method according to claim 18, wherein a trench capacitor for memory is to be formed in the mixture area.

20. The method according to claim 9, wherein the trenches are isolation trenches.
